(19) United States
(12) Patent Application Publication
(10) Pub. No.: US 2026/0239946 A1
(43) Pub. Date: Aug. 13, 2026

(54) STACKED TRANSISTOR WITH ETCH STOP BONDING

(71) Applicant: International Business Machines Corporation, Armonk, NY (US)

(72) Inventors: Debarghya Sarkar, Latham, NY (US); Ruilong Xie, Niskayuna, NY (US); Shay Reboh, Guilderland, NY (US); Junli Wang, Slingerlands, NY (US)

(21) Appl. No.: 19/049,069

(22) Filed: Feb. 10, 2025

(51) Int. Cl. H01L 21/768; H10D 30/00; H10D 30/01; H10D 30/43; H10D 62/10; H10D 62/13; H10D 84/01; H10D 84/85

(52) U.S. Cl. CPC H10W 20/074; H10D 30/014; H10D 30/0194; H10D 30/43; H10D 30/506; H10D 62/121; H10D 62/151; H10D 84/017; H10D 84/851

(57) ABSTRACT

The present disclosure describes fabrication methods and resulting semiconductor integrated circuit (IC) devices that include a stacked transistor with an etch stop bonding structure. The etch stop bonding structure may provide etch stop protection, at least associated with the pre-clean etch and subsequent fabrication of an associated source/drain region of a top transistor. The etch stop bonding structure may protect against or prevent the associated fabricated source/drain region electrically shorting with an adjacent gate structure.

### BACKGROUND

A stacked transistor may include a top transistor stacked upon a bottom transistor. To fabricate the top transistor, a source/drain preclean etch process may gouge an underlying bonding layer to an extent that may result in the associatively formed source/drain to undesirably electrically short to an adjacent gate structure.

### SUMMARY

In an embodiment of the disclosure, a semiconductor integrated circuit (IC) device is presented. The semiconductor IC device includes a top transistor comprising a top source/drain (S/D) region, a bottom transistor, and an etch stop bonding structure. The etch stop bonding structure includes a bonding layer directly connected to the bottom transistor and an etch stop layer directly connected to the top transistor.

In an embodiment of the disclosure, a semiconductor IC device is presented. The semiconductor IC device includes a top transistor comprising a top source/drain (S/D) region, a bottom transistor comprising a bottom S/D region inline and below the top source/drain region, and an etch stop bonding structure. The etch stop bonding structure includes a bonding layer directly connected to the bottom transistor and an etch stop layer directly connected to the top transistor.

In another embodiment of the present disclosure, a semiconductor IC device fabrication method is presented. The method includes forming a bottom transistor, forming a bonding layer upon the bottom transistor, forming an etch stop layer and directly connecting the etch stop layer to the bonding layer, and forming a top transistor upon the etch stop layer. Forming the top transistor includes forming a top source/drain canyon that gouges a portion of the etch stop layer and forming a top source/drain region within the source/drain canyon. Wherein the gouge within the etch stop layer is directly under a bottom surface of the top S/D region.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of a semiconductor IC device that includes a stacked transistor with an etch stop bonding structure, according to one or more embodiments of the disclosure.

FIG. 2 depicts a partial top-down structure view of an illustrative semiconductor IC device and establishes a cross-sectional plane for the views of the semiconductor IC devices of FIG. 3 through FIG. 7, according to one or more embodiments of the disclosure.

FIG. 3 through FIG. 7 depict various fabrication structure cross-section views of an illustrative semiconductor IC device that includes a stacked transistor with an etch stop bonding structure, according to one or more embodiments of the disclosure.

FIG. 8 depicts a method of fabricating a semiconductor IC device that includes a stacked transistor with an etch stop bonding structure, according to one or more embodiments of the disclosure.

### DETAILED DESCRIPTION

The present disclosure relates to fabrication methods and resulting semiconductor integrated circuit (IC) devices that include a stacked transistor with an etch stop bonding structure. The etch stop bonding structure may provide robust or adequate etch stop protection, at least associated with the pre-clean etch and subsequent fabrication of an associated source/drain region of a top transistor. The etch stop etch stop bonding structure may protect against or prevent the associated fabricated source/drain region electrically shorting with an adjacent gate structure.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “top,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and, more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., polysilicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths. Integration of multiple transistors, such as a bottom transistor and a top transistor, into a stacked configuration may allow for continued device scaling. However, there are many fabrication challenges in order to form stacked transistors at scale.

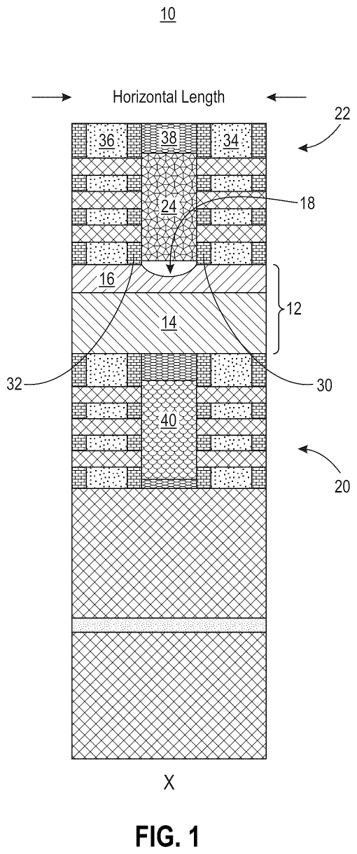

Please refer to FIG. 1, that depicts a cross-section view of a semiconductor IC device 10 that includes an etch stop bonding structure 12. In an embodiment, the semiconductor IC device 10 further includes a top transistor 22 that at least includes a top source/drain (S/D) region 24 and a bottom transistor 20. The etch stop bonding structure 12 includes a bonding layer 14 directly connected to the bottom transistor 20 and an etch stop layer 16 directly connected to the top transistor 22.

In an example, the semiconductor IC device 10 further includes a gouge 18 within the etch stop layer 16 located directly under a bottom surface of the top S/D region 24. In an example, the etch stop layer is composed of a dielectric material that has a dielectric constant (κ) of four or less, which may improve the electrical isolation between the top transistor 22 and the bottom transistor 20.

In an example, a horizontal length of the top S/D region 24 is substantially the same as a horizontal length of the gouge 18. In an example, the semiconductor IC device 10 further includes a first bottommost inner spacer 30 directly connected to the etch stop layer 16 and directly connected to the top S/D region 24 and a second bottommost inner spacer 32 directly connected to the etch stop layer 16 and directly connected to the S/D region 24.

In an example, the first bottommost inner spacer 30 is further directly connected to a first gate structure 34 and wherein the second bottommost inner spacer 32 is further directly connected to a second gate structure 36.

In an example, a horizontal length of the top S/D region 24 is greater than a horizontal length of the gouge 18. In an example, a horizontal length of the top S/D region 24 is less than a horizontal length of the gouge 18. In this example, the gouge 18 is between at least a portion of a bottom surface of the first inner spacer 30 and the etch stop layer 16 and between at least a portion of a bottom surface of the second inner spacer 30 and the etch stop layer 16. In an example, the gouge 18 is substantially filled with air. In an example, the gouge 18 is substantially filled with the top S/D region 24. In an example, the gouge 18 is substantially filled with a dielectric material (e.g., interlayer dielectric 38, etc.) that is different from the etch stop layer 16.

In another embodiment of the present disclosure, another instance of semiconductor IC device 10 is presented. The semiconductor IC device 10 includes the top transistor 22 that has the top source/drain region 24, the bottom transistor 20 that has a bottom S/D region 40 inline and below the top source/drain region 24, and the etch stop bonding structure 12 that includes the bonding layer 14 directly connected to the bottom transistor 20 and the etch stop layer 16 directly connected to the top transistor 22.

In another embodiment of the present disclosure, a semiconductor integrated circuit (IC) device fabrication method is presented. The method includes forming the bottom transistor 20, forming the bonding layer 14 upon the bottom transistor 20, forming the etch stop layer 16 upon the bonding layer 14, and forming the top transistor 22 upon the etch stop layer 16. Forming the top transistor 22 comprises forming a top source/drain canyon that gouges a portion of the etch stop layer 16. For example, gouge 18 is formed within the etch stop layer 16. The method further includes forming the top source/drain region 24 within the source/drain canyon. In the method, the gouge 18 within the etch stop layer 16 is directly under the bottom surface of the top S/D region 24.

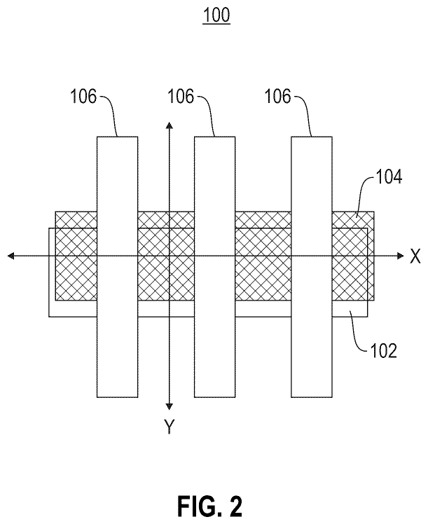

FIG. 2 depicts a partial top-down structure view of a semiconductor IC device 100 and establishes an illustrative cross-sectional plane Y1 for the views of the semiconductor IC device structures of the disclosure. The illustrated semiconductor IC device 100 includes a top transistor active region 104 and a bottom transistor active region 102. As depicted, the top transistor active region 104 overlaps or is in line with the bottom transistor active region 102. Top S/D region(s) of the top transistor may be formed within the top transistor active region 104 between gate structures 106. Similarly, bottom S/D region(s) of the bottom transistor may be formed within the bottom transistor active region 102 between gate structures 106.

FIG. 2 depicts a plane Y across the bottom transistor active region 102 and across the top transistor active region 104 in between adjacent gate structures 106. FIG. 2 further depicts a plane X across the bottom transistor active region 102 and across the top transistor active region 104 and across one or more gate structures 106.

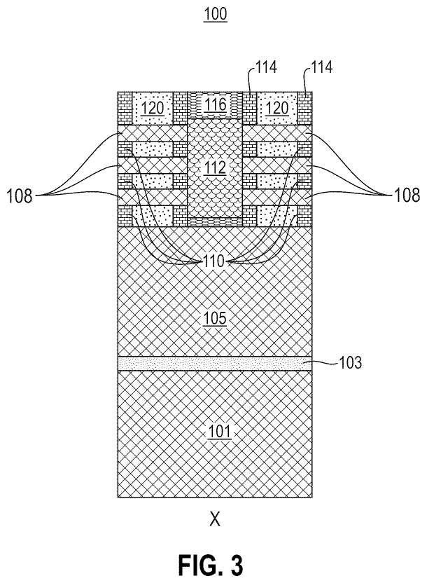

FIG. 3 depicts an initial fabrication structure cross-section view of an illustrative semiconductor IC device 100, according to one or more embodiments of the disclosure. For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 3, such associated component numeral is expressly utilized. Otherwise, when components are referenced in the illustrative methodology that are not depicted in FIG. 3, a component numeral is not denoted.

The illustrative semiconductor IC device 100 may be formed by initially providing or forming a substrate structure. The substrate structure may be a bulk-semiconductor substrate. In one example, the bulk-semiconductor substrate may be a silicon-containing material. In the depicted implementation, the substrate structure includes a top substrate 105, a lower substrate 101, and an etch stop layer 103 between the top substrate 105 and the lower substrate 101. The top substrate 105 and the lower substrate 101 may be comprised of any suitable silicon-containing material(s), and the etch stop layer 103 may be a dielectric material with etch selectivity to one or both top substrate 105 and/or the lower substrate 101. In one example, the etch stop layer 103 may be an oxide and the substrate structure may be referred to as a buried oxide (BOX) substrate. In a particular example, the lower substrate 101 may be composed of silicon. The etch stop layer 103 may be composed of Silicon Germanium (SiGe) and may be epitaxially grown from the top surface of lower substrate 101 and the top substrate 105 may be composed of Si and may be epitaxially grown from the top surface of etch stop layer 103.

Next, the illustrative semiconductor IC device 100 may be formed by forming nanolayers over the substrate structure by forming a bottommost sacrificial nanolayer (not shown) and by forming a series of alternating sacrificial nanolayers (not shown) and active nanolayers 108 thereupon. In an implementation, the alternating active sacrificial nanolayer and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the bottommost sacrificial nanolayer and the sacrificial nanolayers can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottommost sacrificial nanolayer, the sacrificial nanolayers, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

The nanolayers may be patterned into nanolayer rows and shallow trench isolation (STI) regions (not shown) may be formed. To form the nanolayer rows, a mask layer may be formed on the topmost nanolayer. The mask layer may be comprised of any suitable mask material(s). Utilizing photolithography and etching techniques, the mask layer may be patterned and used to perform the nanolayer stack patterning process. In the nanolayer stack patterning process, any suitable material removal process (e.g., reactive ion etching or RIE) may be used to remove portions of the alternating nanolayers down to the level of the substrate structure, or the like. Following the nanolayer stack patterning process, the one or more nanolayer rows are formed and the mask layer may be removed.

The removal of undesired portion(s) of the alternating nanolayers may further remove undesired portions of substrate structure that are adjacent to respective footprints of nanolayer rows to form STI region openings. The etch may be timed or otherwise controlled to stop the removal of the substrate structure such that the depth or bottom of the one or more STI region openings has a predetermined or desired dimension. For example, the depth or bottom of the one or more STI region openings may be above the etch stop layer 103, as depicted. In some examples, the etch to form the nanolayer rows may utilize the etch stop layer 103 to stop the etch and form the bottom well of the one or more STI region openings.

A STI region may be formed upon and/or within the substrate structure within respective STI region openings. The STI regions may be formed by depositing electrical dielectric material(s) within respective STI region opening(s) that are adjacent to the one or more nanolayer rows. A top surface of the one or more STI regions may be initially coplanar with or below a top surface of the substrate structure. In some implementations, further fabrication operations may generally remove portions of the STI regions (e.g., sacrificial gate removal, replacement gate fabrication pre-clean, etc.), such that the top surfaces of the STI regions are below the top surface of the substrate structure.

The one or more STI regions may have a volume and/or geometry that sufficiently electrically isolates components or features of neighboring bottom transistors, or the like, may sufficiently electrically isolate neighboring nanolayer rows.

In an example, the STI regions may be formed by depositing a STI liner within the STI region openings. Subsequently, STI regions may be further formed by depositing STI dielectric material upon the STI liner. A etch back, recess, or the like, may occur to remove undesired or over formed STI liner and/or STI dielectric material, such that the top surface of the STI regions are coplanar with or below a bottom surface of the bottommost sacrificial nanolayer. STI liner may be composed of but not limited to a nitride, low-K nitride (e.g., a nitride material with a lower dielectric constant relative to SiO₂), or the like. The STI dielectric material may be composed of but not limited to an oxide, low-K oxide (e.g., an oxide material with a lower dielectric constant relative to SiO₂), or the like.

The illustrated semiconductor IC device 100 may be further fabricated by next forming sacrificial gate structures (not shown). The one or more sacrificial gate structures may be formed by patterning a gate cap layer, sacrificial gate layer, and sacrificial gate liner that are formed upon the nanolayers and STI regions by, for example, using lithography and etch processes to remove undesired portions and retain desired portion(s), respectively. The retained desired portion(s) of the gate cap layer, sacrificial gate layer, and sacrificial gate liner may form a sacrificial gate liner, a sacrificial gate, and a sacrificial gate cap, respectively, of each of the one or more sacrificial gate structures. One or more sacrificial gate structures can be formed on targeted regions or areas of semiconductor IC device 100 to define the length of one or more GAA FETs and to provide sacrificial material for yielding targeted GAA FET structure(s) in subsequent processing.

The semiconductor IC device 100 may be further fabricated by forming gate spacers 114 upon the sidewall(s) of the sacrificial gate structures, upon the STI regions, and around the one or more nanolayer rows. The semiconductor IC device 100 may be further fabricated by next forming source/drain (S/D) recesses within the one or more nanolayer rows between gate spacers 114 of neighboring sacrificial gate structures. In other words, a single nanolayer row may be separated, by one or more S/D recesses, into multiple nanolayer stacks each located underneath at a portion of respective sacrificial gate structure and associated gate spacer 114. The undesired portions of sacrificial nanolayers, active nanolayers 108, and the like, may be removed by etching or other subtractive removal techniques. As the gate spacers 114 and the sacrificial gate structures may be utilized to protect the underlying portions of sacrificial nanolayers and active nanolayers 108, respective sidewalls of the nanolayer rows may be substantially coplanar and substantially vertical with the outer sidewalls of the gate spacers 114 there above.

As used herein, “substantially vertical” sidewalls deviate from a direction normal to a major surface (e.g., top surface, etc.) of the substrate 105 by less than 5°, e.g., 0°, 1°, 2°, 3°, 4°, or 5°, including ranges between any of the foregoing values.

The illustrated semiconductor IC device 100 may be further fabricated by forming horizontal or lateral indents by laterally or horizontally removing respective portions of sacrificial nanolayers within the nanolayer stacks. The indents may be formed by a reactive ion etch (RIE) process, which can remove portions of the sacrificial nanolayers. The illustrated semiconductor IC device 100 may be further fabricated by forming a respective inner spacer 110 within each indent. The one or more inner spacers 110 can be formed by ALD or CVD or any other suitable deposition technique that deposits a dielectric material within the indent(s), thereby forming the inner spacer(s). In some examples, the inner spacer 110 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacer(s) 110, an isotropic etch process is performed to create substantially vertical sidewalls of the inner spacer(s) 110 that are coplanar with the substantially vertical sidewalls of the active nanolayers 108, of the gate spacers 114, etc.

The illustrated semiconductor IC device 100 may be further fabricated by forming a respective S/D region 112. Each S/D region 112 may form either a source or a drain, respectively, of respective transistors and is connected to respective end surface of the active nanolayers 108 of a nanolayer stack. Each S/D region 112 is composed of a semiconductor material and a dopant. As used herein, a “source/drain” region can be a source region or a drain region depending on subsequent wiring and application of voltages during operation of the applicable transistor. The semiconductor material that provides each of the S/D regions 112 may be composed of one of the semiconductor materials mentioned above for the semiconductor structure. For example, the semiconductor material that provides the S/D region 112 can be compositionally the same, or compositionally different from each active nanolayer 108. The dopant that is present in the S/D region 112 can be either a p-type dopant or an n-type dopant. The term “p-type” refers to the addition of impurities to an intrinsic semiconductor that creates deficiencies of valence electrons, and “n-type” refers to the addition of impurities that contributes free electrons to an intrinsic semiconductor.

The one or more S/D regions 112 may be epitaxially grown or formed. In some examples, the S/D region 112 are formed by in-situ doped epitaxial growth or an ex-situ process may be employed to introduce dopants into the S/D regions 112. Other doping techniques can be used to incorporate dopants in the S/D regions 112.

In some examples, the epitaxial growth that forms the S/D region 112 occurs or is promoted from the top surface of top substrate 105, and/or from the end surfaces of the active nanolayers 108, while epitaxial growth may be limited or does not occur from neighboring STI regions.

The illustrated semiconductor IC device 100 may be further fabricated by next forming interlayer dielectric (ILD) 116. For example, a blanket ILD 116 may be deposited over the S/D region(s) 112, over the STI regions, over the sacrificial gate structures, and over the gate spacers 114, and the like.

The ILD 116 can be any suitable material, such as, for example, porous silicates, carbon doped oxides, silicon dioxides, silicon nitrides, silicon oxynitrides, OPL, or other dielectric materials. In an example, the ILD 116 may be formed to a thickness above the top surface of the sacrificial gate structures. Subsequently, a planarization process, such as a CMP, may be performed to remove excess ILD 116 material and to remove the sacrificial gate caps of the sacrificial gate structures, thereby exposing the sacrificial gate thereunder. The planarization may also partially remove some of the sacrificial gates or may at least expose the sacrificial gate of the sacrificial gate structures.

The illustrated semiconductor IC device 100 may be further fabricated by removing the sacrificial gate structures and releasing the active nanolayers 108 within the nanolayer stacks. The sacrificial nanolayers may be removed by a removal technique, such as one or more series of etches. For example, the etching can include a wet chemical etching process in which one or more chemical etchants are used to remove the sacrificial nanolayers.

The illustrated semiconductor IC device 100 may be further fabricated by forming a replacement gate structure 120 in place of the removed sacrificial gate structures around the active nanolayers 108, upon STI regions, etc. Replacement gate structures 120 may be formed by initially forming an interfacial layer on the gate spacers 114, on the active nanolayers 108, on the inner spacers 110, etc. that are interior to and/or upon the respective surfaces interior to the opening created by the removal of the sacrificial gate structure and the releasing of the active nanolayers 108. The interfacial layer can be deposited by any suitable techniques, such as ALD, CVD, PVD, thermal oxidation, combinations thereof, or other suitable techniques.

Replacement gate structures 120 may be further formed by forming a high-k layer to cover the exposed surfaces of the interfacial layer. The high-K layer can be deposited by any suitable techniques, such as ALD, CVD, metal-organic CVD (MOCVD), PVD, thermal oxidation, combinations thereof, or other suitable techniques. A high-K material is a material with a higher dielectric constant than that of SiO₂. The replacement gate structures 120 may be further formed by depositing a work function (WF) gate upon the high-K layer. The WF gate sets the threshold voltage (Vt) of the device. The high-K layer may separate the WF gate from the nanolayer channel (e.g., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structures 120 may be further formed by depositing a conductive gate. In an example, when none of the previous replacement gate material(s) are utilized in the replacement gate structures 450, the conductive gate may be formed upon the same or similar surfaces as those upon which the interfacial layer, described above, may be formed. In other examples, when one or more of the interfacial layer, the high-K layer, the WF gate, or the like, are utilized in the replacement gate structures, the conductive gate may be formed upon the most recent structural formation thereof. The conductive gate can be comprised of a conductor material and/or metal, such as but not limited to, e.g., tungsten, aluminum, ruthenium, rhodium, cobalt, copper, tantalum, titanium, or the like. After the replacement gate structure 120 formation, the top surface of the semiconductor IC device 100 may be planarized by a planarization technique such as a CMP, mechanical grinding process, or the like.

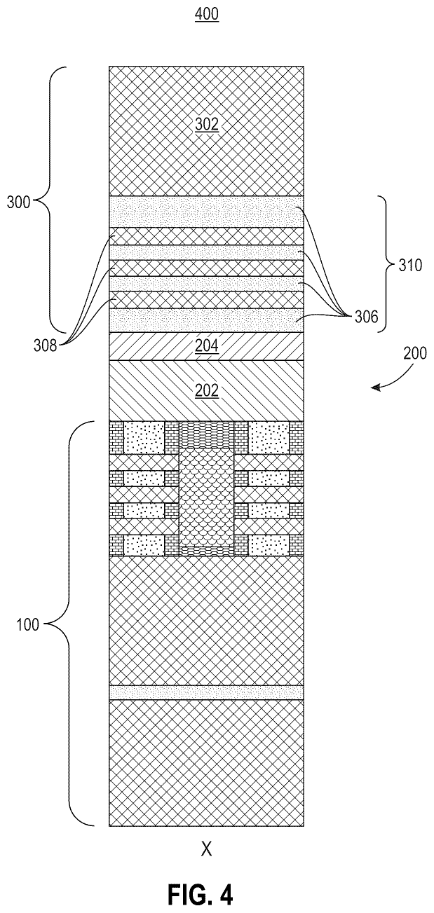

FIG. 4 depicts cross-sectional views of a semiconductor IC device 400 shown after representative fabrication operation(s), in accordance with one or more embodiments. In the depicted fabrication stage, a semiconductor IC device 300 that includes top transistor nanolayers may be bonded to the semiconductor IC device 100.

For example, top transistor nanolayers 310, which includes a substrate 302 and alternating active nanolayers 308 and sacrificial nanolayers 306 may be bonded to the semiconductor IC device 100 by an etch stop bonding structure 200. In such process, semiconductor IC device 300 that includes the substrate 302 and the top transistor nanolayers 310 may be bonded to semiconductor IC device 100. Etch stop bonding structure 200 may include a bonding layer 202, which may be e.g., a bonding oxide, nitride, or other dielectric, and may further include an etch stop layer 204. The etch stop layer 204 generally has appropriate etch selectivity to the other structures, as appropriate and consistent with that which is described. In a particular embodiment, the etch stop layer 204 may be composed of a low-K dielectric material that has a dielectric constant of four or less. This may improve or provide adequate electrical isolation between features of the semiconductor IC device 300 and features of the semiconductor IC device 100. In particular examples, the etch stop layer 204 may be composed of SiCO, SiN, SiBCN, SiOCN, or the like. Any known manner of forming the bonding layer 202 and the etch stop layer 204 can be utilized. The bonding layer 202 and the etch stop layer 204 can be formed using, for example, CVD, PECVD, ALD, flowable CVD, spin-on dielectrics, PVD, or the like.

In embodiments, the bonding layer 202 may be a blanket layer formed upon or otherwise associated with the top surface of the entire semiconductor IC device 100. Similarly, the etch stop layer 204 may be a blanket layer formed upon or otherwise associated with the top surface of the bonding layer 202. In an example, the bonding layer 202 may be formed upon the top surface of the semiconductor IC device 100 and the etch stop layer 204 may formed upon the bottom surface of the semiconductor IC device 300 prior to the semiconductor IC device 300 being bonded to the semiconductor IC device 100. After wafer-to-wafer bonding, the substrate 302 may be removed, and the top transistor nanolayers 310 are retained and otherwise associated with the substrate structure by etch stop bonding structure 200.

In the example illustrated, there are a total of four sacrificial nanolayers and three active nanolayers 308 that are alternately formed to create the top transistor nanolayers 310. However, it should be appreciated that any suitable number of alternating layers may be formed. Although it is specifically contemplated that the sacrificial nanolayers can be formed from SiGe and that the active nanolayers 308 can be formed from Si, it should be understood that any appropriate materials can be used instead, as long as the two semiconductor materials have etch selectivity with respect to one another.

In certain embodiments, the sacrificial nanolayers have a vertical thickness ranging, for example, from approximately 3 nm to approximately 20 nm. In certain embodiments, the active nanolayers 308 have a vertical thickness ranging, for example, from approximately 3 nm to approximately 10 nm. Although the range of 3-20 nm is cited as an example range of thickness, other thickness of these layers may be used. In certain examples, certain of the sacrificial nanolayers or the active nanolayers 308 may have different thicknesses relative to one another. Therefore, multiple epitaxial growth processes can be performed to form the alternating top transistor nanolayers 310.

In certain embodiments, it may be desirable to have a VSP between adjacent top transistor nanolayers 310 to reduce the parasitic capacitance and to improve circuit speed. For example, the VSP (the distance between adjacent active nanolayers 308) may range from 5 nm to 15 nm. However, the VSP should be of sufficient value to accommodate the replacement gate that will be formed in the spaces created by later removal of respective portions of the sacrificial nanolayers.

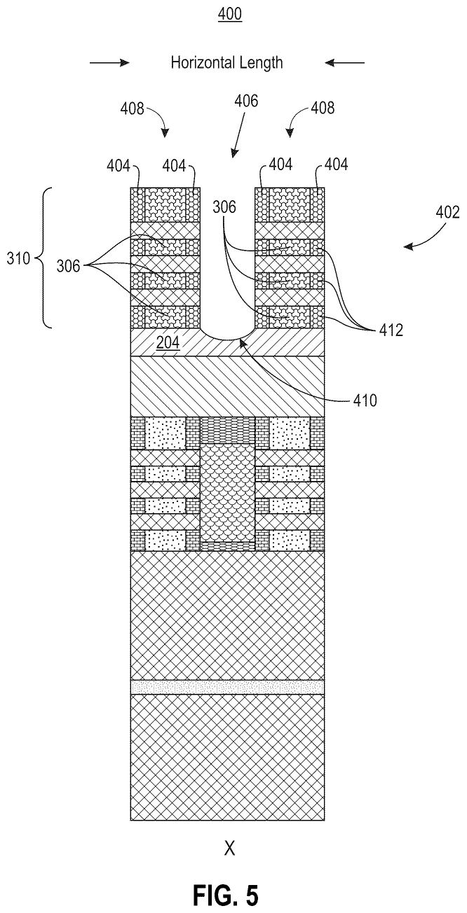

FIG. 5 depicts cross-sectional views of semiconductor IC device 100 shown after representative fabrication operation(s), in accordance with one or more embodiments. In the depicted stages, the top transistor nanolayers 310 may be patterned, sacrificial gates may be formed, top gate spacers 404 may be formed, top S/D canyons 406 may be formed, and top inner spacers 412 may be formed.

For example, the top transistor nanolayers 310 may be patterned into nanolayer rows 402. To form one or more nanolayer rows 402, a mask layer (not shown) may be formed on the topmost nanolayer of the top transistor nanolayers 310. The mask layer may be comprised of any suitable mask material(s). The mask layer may be patterned and used to perform the nanolayer row 402 patterning process. In the nanolayer row 402 patterning process, any suitable material removal process (e.g., reactive ion etching or RIE) may be used to remove portions of the alternating top transistor nanolayers 310 down to the level of the etch stop layer 204, or the like. Following the nanolayer row 402 patterning process, one or more nanolayer rows 402 are formed. Subsequently, the mask layer may be removed.

One or more top sacrificial gate structures (not shown) may be formed over the one or more nanolayer rows 402 and may include a top sacrificial gate liner (not shown), a top sacrificial gate (not shown), and a top sacrificial gate cap (not shown). The top sacrificial gate structures may be formed by initially depositing a top sacrificial gate liner layer (e.g., a dielectric, oxide, or the like) upon the etch stop layer 204 and upon and around the one or more nanolayer rows 402. The top sacrificial gate structures may further be formed by subsequently depositing a top sacrificial gate layer (e.g., amorphous silicon, or the like) upon the top sacrificial gate liner layer. The thickness of the top sacrificial gate layer may be such that the top surface of the top sacrificial gate layer is above the top surface of the one or more nanolayer rows 402. The top sacrificial gate structures may further be formed by forming a gate cap layer upon the top sacrificial gate layer. The gate cap layer may be formed by depositing a mask material, such as a hard mask material, such as silicon nitride, silicon oxide, combinations thereof, or the like, upon the top sacrificial gate layer. The gate cap layer may be composed of one or more layers of masking materials to protect the top sacrificial gate layer and/or other underlying materials during subsequent processing of semiconductor IC device 400.

The one or more top sacrificial gate structures may further be formed by patterning the gate cap layer, top sacrificial gate layer, and top sacrificial gate liner by, for example, using lithography and etch processes to remove undesired portions and retain desired portion(s), respectively. The retained portion(s) of the gate cap layer, top sacrificial gate layer, and top sacrificial gate liner may form the top sacrificial gate liner (not shown), the top sacrificial gate (not shown), and the top sacrificial gate cap (not shown), respectively, of each of the one or more top sacrificial gate structures.

One or more top sacrificial gate structures can be formed on targeted regions or areas of semiconductor IC device 400 to define the gate length of one or more top transistors and to provide sacrificial material for yielding targeted top transistor structure(s) in subsequent processing. In embodiments, a respective top sacrificial gate structure may be formed in line with a particular lower sacrificial gate structure.

Further in the depicted fabrication stages, top gate spacers 404 may be formed. The top gate spacers 404 may be formed upon the sidewall(s) of the top sacrificial gate structures, upon the etch stop layer 204, and around the one or more nanolayer rows 402. The top gate spacers 404 may be formed by a conformal deposition of a dielectric material, such as silicon nitride, SiBCN, SiNC, SiN, SiCO, SiNOC, or a combination thereof, or the like, upon etch stop layer 204, upon and around the one or more top sacrificial gate structures, and upon and around the one or more nanolayer rows 402. Subsequently, undesired portions of dielectric material may be removed while desired portions the dielectric material may be retained and thereby form the top gate spacer(s). The undesired portions of dielectric material may be removed by a directional ion etch, such as a reactive ion etch (RIE).

Further in the depicted fabrication stages, top source/drain (S/D) canyons 406 may be formed within the one or more nanolayer rows 402 between top gate spacers 404 of neighboring top sacrificial gate structures. In other words, a single nanolayer row 402 may be separated, by a top S/D recess, into multiple nanolayer stacks 408 each located underneath a respective top sacrificial gate structure. The one or more top S/D canyons 406 may be formed between adjacent top sacrificial gate structures by removing respective portions of the top transistor nanolayers 310, that are between top gate spacers of adjacent or neighboring top sacrificial gate structures. The one or more top S/D canyons 406 may be formed to a depth to stop at the top surface of the etch stop layer 204, or the like. Alternatively, as depicted, the one or more top S/D canyons 406 may be formed to a depth to below the top surface of the etch stop layer 204, thereby forming a gouge 410 within the etch stop layer 204 within the top S/D canyon 406 regions. A horizontal length of gouge 410 may be substantially equal to a horizontal length or pitch between sacrificial gate structures when the formation of the S/D canyon 406 regions is highly selective relative to the materials of the top transistor nanolayers 310. In some instances, the gouge 410 may slightly undercut the sacrificial gate structures. However, the etch stop layer 204 adds adequate etch control to limit such undercuts to reduce the propensity of an associated S/D region to electrically short with adjacent gate structure(s). For clarity, gouge 410 may be located entirely within the etch stop layer 204. For example, any part of the underlying bonding layer 202 may not effectively form a wall or boundary of the gouge 410.

The undesired portions of top transistor nanolayers 310 may be removed by etching or other subtractive removal techniques. The top surface of the etch stop layer 204 may be used as an etch stop or other etch parameters may be controlled to stop the material removal at the etch stop layer 204. As the top gate spacers 404 and the top sacrificial gate structures may be utilized to protect the underlying portions of top transistor nanolayers 310, respective sidewalls of the nanolayer stacks 408 may be substantially coplanar and/or substantially vertical with the outer sidewalls of the top gate spacers 404, there above.

Further in the depicted fabrication stages, sacrificial nanolayers may be indented and a respective top inner spacer may be formed in each indent. For example, horizontal or lateral indents may be formed by laterally or horizontally (e.g., into and/or out of the page of the depicted Y1 cross-section) removing respective portions of sacrificial nanolayers within the nanolayer stacks 408. The indents may be formed by a reactive ion etch (RIE) process, which can remove portions of the sacrificial nanolayers. The horizontal depth of the indents may be chosen to set a length for a replacement gate structure that is formed in place of one top sacrificial gate structure. When the sacrificial nanolayers are composed of SiGe and when active nanolayers 308 are Si, the directional RIE can use a boron-based chemistry or a chlorine-based chemistry, for example, which recesses or removes the exposed end portions of sacrificial nanolayers (e.g., end portions of sacrificial nanolayers generally below the gate spacer) selective to the Si active nanolayers 308. In alternative implementations when sacrificial nanolayers are not SiGe and when active nanolayers 308 are not Si, the directional etch of the sacrificial nanolayers may generally be selective to the active nanolayers 308, top gate spacers, and/or etch stop layer 204.

Further in the depicted fabrication stages, a respective top inner spacer 412 may be formed within each indent. The one or more top inner spacers 412 can be formed by ALD or CVD or any other suitable deposition technique that deposits a dielectric material within the indent(s), thereby forming the top inner spacer(s). In some examples, the top inner spacers 412 are composed of a low-K dielectric material, SiN, SiO, SiBCN, SiOCN, SiCO, etc. or any other suitable dielectric material. In certain implementations, after the formation of the top inner spacer 412, an isotropic etch process is performed to create substantially vertical sidewalls of the top inner spacer 412 that are coplanar with the substantially vertical sidewalls of the active nanolayers 308, of the top gate spacers 404, or the like.

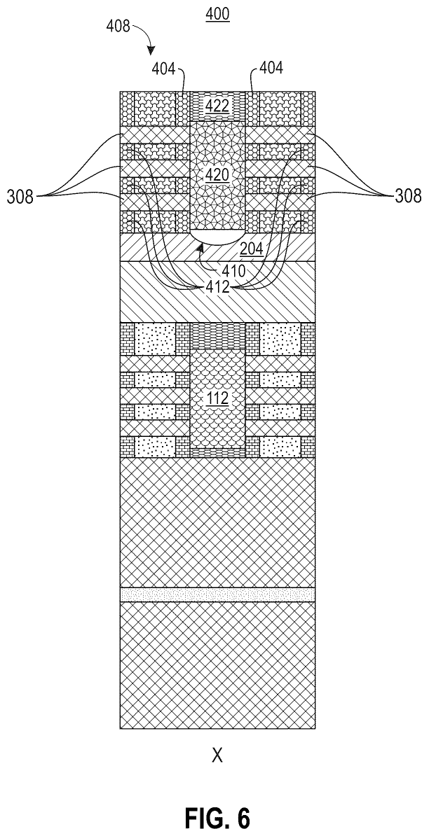

FIG. 6 depicts cross-sectional views of the semiconductor IC device 100 after fabrication operations, in accordance with embodiments of the present disclosure. In the depicted fabrication stages, a top S/D region 420 and a top ILD 422 may be formed.

The top S/D region 420 forms either a source or a drain, respectively, of respective top transistor, such as a GAA FET, and is connected to respective a side or end surface of the active nanolayers 308 of adjacent top nanolayer stacks 408. The top S/D region 420 may be composed of a semiconductor material and a dopant. The semiconductor material that provides each top S/D region 420 may be composed of one of the semiconductor materials mentioned above for the semiconductor structure. The semiconductor material that provides the top S/D region 420 can be compositionally the same, or compositionally different from each active nanolayers 308. The dopant that is present in the top S/D region 420 can be either a p-type dopant or an n-type dopant. The top S/D region 420 may be in line with the bottom S/D region 112. For example, the top S/D region 420 may share a same or substantially same vertical bisector as the bottom S/D region 112.

The one or more top S/D regions 420 may be epitaxially grown or formed from the exposed end surfaces of the active nanolayers 308), while epitaxial growth is limited or does not occur from etch stop layer 204. In some examples, the top S/D regions 420 may be formed by in situ doped epitaxial growth. The use of an in situ doping process is merely an example. For instance, one may instead employ an ex situ process to introduce dopants into the source and drains. Other doping techniques can be used to incorporate dopants in the top source/drain region 420. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some examples, the epitaxial growth that forms the one or more top S/D region 420 occurs or is promoted from the exposed end or side surfaces of the top active nanolayers 308, while epitaxial growth is limited or does not occur from neighboring etch stop layer 204 or inner spacers 412.

In some embodiments, epitaxial growth to form the one or more top S/D regions 420 may overgrow above the top surface of the top sacrificial gate structure(s) and be subsequently recessed such that the top surface of the top S/D region 420 may be substantially horizontal and above the top surface of the topmost active nanolayer 308 within the nanolayer stacks 408 (e.g., to enable contact between this active nanolayer 308 and the top S/D region 420).

In one example, the formation of the one or more of the top S/D regions 420 may fill the gouge 410. In another example, as depicted, the formation of the one or more top S/D region 420 may not entirely fill the gouge 410. In these embodiments, the combination of the gouge 410 within the etch stop layer 204 and the shape of the top S/D regions 420 may form and air pocket.

The air pocket may be a material void or airgap and is present between the bottom of the top S/D region 420 and the etch stop layer 204. The air pocket may reduce the parasitic capacitance between the top S/D region 420 and the bottom transistor.

In some embodiments, the air pocket results from a deposition or formation process of the top S/D region 420 in combination with a predefined geometry relationship of the gouge 410. For example, when the gouge 410 is sufficiently large compared to the formation or volume of the top S/D region 420, the top S/D region 420 may be sufficiently formed prior to the gouge 410 being completely filled.

Different instances of the air pocket may have relative differences in shape, size, location, or the like, because of manufacturing tolerance effects and/or to independently improve or optimize parasitic capacitance decreases associated with the stacked transistors.

For clarity, while referred to as an “air pocket” in this description, the air pocket may contain gases different from those commonly associated with air and its composition. As such, air pocket can also be referred to as a void, pocket, bubble, or other terminology. Also, the air pocket can be distinguished from small imperfections that may be randomly positioned throughout a material, or imperfections of junctions or interfaces between the top S/D region 420 and the etch stop layer 204, based on the gouge 410 having a significantly greater size and being aligned between gate structures and below the top S/D region 420. Further, while illustrated in the X cross-sectional views, as having an illustrative cross-sectional shape, such shape may not represent the actual shape and the air-pocket as it can have other cross-sectional shapes, including round, elliptical, trapezoidal, or other irregular or elongated shapes.

Further in the depicted fabrication stages, a top interlayer dielectric (ILD) 422 may be formed. For example, a blanket top ILD 422 material may be deposited over the top S/D region(s) 420, upon the etch stop layer 204, over the top sacrificial gate structures, and over the top gate spacers 404 associated with adjacent top sacrificial gate structures.

The top ILD 422 can be any suitable material, such as, for example, porous silicates, carbon doped oxides, silicon dioxides, silicon nitrides, silicon oxynitrides, OPL, or other dielectric materials. Any known manner of forming the top ILD 422 can be utilized. The top ILD 422 can be formed using, for example, CVD, PECVD, ALD, flowable CVD, spin-on dielectrics, or PVD.

In an example, the top ILD 422 may be formed to a thickness above the top surface of the top sacrificial gate structures. Subsequently, a planarization process, such as a CMP, may be performed to remove excess top ILD 422 material and to remove the top sacrificial gate caps of the top sacrificial gate structures, thereby exposing the top sacrificial gate thereunder. The planarization may also partially remove some of the top sacrificial gates or may at least expose the top sacrificial gate of the top sacrificial gate structures. The CMP may create a substantially planar or substantially horizontal top surface for the semiconductor IC device 400. In other words, the respective top surfaces of the top ILD 422, top gate spacers 404, top sacrificial gates, etc. may be substantially coplanar and/or substantially horizontal.

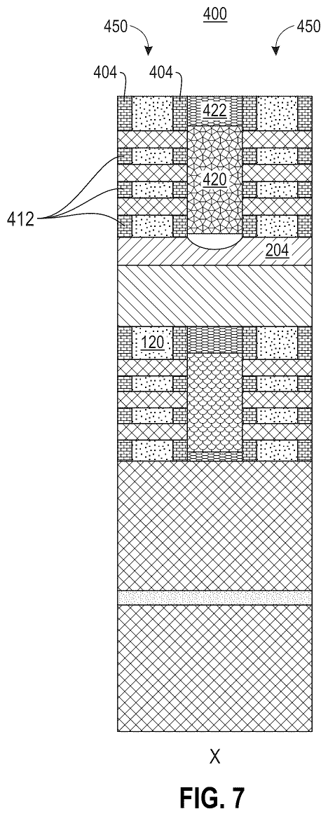

FIG. 7 depicts cross-sectional views of the semiconductor IC device 100 after fabrication operations, in accordance with embodiments of the present disclosure. In the depicted fabrication stages, top replacement gate structures 450 may be formed.

The top replacement gate structures 450 may be formed by removing the top sacrificial gate structures. For example, one or more replacement gate opening(s) (not shown) may be formed by removing the sacrificial gate structures. The one or more replacement gate opening(s) may be formed by lithography and etch process, where a mask (not shown) may be applied and patterned. An opening in the patterned mask may expose the portion of the underlying top sacrificial gate structure to be removed between top gate spacers, while other protected portions of top sacrificial gate structure thereunder may be protected and retained. The one or more replacement gate opening(s) may be formed to a depth stopping at the etch stop layer 204.

Further, in the depicted fabrication stage(s), the top sacrificial gate structures and the lower sacrificial gate structures may be removed which may form a replacement gate structure opening. The top sacrificial gate structures and the lower sacrificial gate structures may be removed by a selective etch of the top gate and bottom gate material through the one or more replacement gate opening(s). In a particular embodiment, the removal of the sacrificial gate structures may further remove the sacrificial nanolayers 306. Therefore, void spaces may exist between the retained active semiconductor nanolayers 308. Therefore, the active semiconductor nanolayers 308 may be referred to as released. It should be appreciated that during the removal of the sacrificial gate structures appropriate etchants are used that do not significantly remove material of active semiconductor nanolayers 308, etch stop layer 204, top gate spacers 404, top inner spacers 412, or the like.

Further, at the present stages of fabrication, replacement gate structure(s) 450 are formed in place of the removed lower sacrificial gate structure(s) around one or more active semiconductor nanolayers 308. For clarity, the replacement gate structure 450 may be a distinct gate structure relative to the bottom gate structure 120. In an example, the top replacement gate structure 450 may be inline with the bottom replacement gate structure 120.

A replacement gate structure 450 may be formed by initially forming an interfacial layer (not shown) on the interior surfaces of the replacement gate opening. Then, a high-K layer (not shown) may be formed to cover the surfaces of exposed surfaces of the interfacial layer. The high-K layer can be deposited by any suitable techniques, such as ALD, CVD, metal-organic CVD (MOCVD), physical vapor deposition (PVD), thermal oxidation, combinations thereof, or other suitable techniques. A high-K dielectric material is a material with a higher dielectric constant than that of SiO₂, and can include e.g., LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials.

The replacement gate structure may be further formed by depositing a work function metal (WFM) gate upon the high-k layer. The replacement gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the replacement gate can be reduced by chemical-mechanical polishing (CMP) and/or etching. Therefore, the planarization process can be provided by CMP. Other planarization process can include grinding and polishing. In general, the replacement gate sets the threshold voltage (Vt) of the top transistors and the bottom transistors. The high-K layer may separate the replacement gate from the active semiconductor nanolayers 308 and the active semiconductor nanolayers 108. Other metals that may be desired to further fine tune the effective work function (eWF) and/or to achieve a desired resistance value associated with current flow through the replacement gate structure.

Next, a metal fill may be formed over the WFM gate. The metal layer may include, e.g., Ti, Ag, Al, TiAlN, TaC, TaCN, TaSiN, Mn, Zr, TiN, TaN, Ru, Mo, Al, WN, Cu, W, or any suitable materials. After the replacement gate structure 450 formation, the top surface of the semiconductor IC device 400 may be planarized by a planarization technique such as a CMP, mechanical grinding process, or the like.

The semiconductor IC device 400 may undergo further fabrication stages to form a final semiconductor IC device. For example, a frontside contact ILD may be formed, middle of the line (MOL) frontside contacts may be formed, a front side back end of line (BEOL) network may be formed, the substrate structure may be removed, a backside contact ILD may be formed upon the backside, backside contacts may be formed, and a backside BEOL network may be formed.

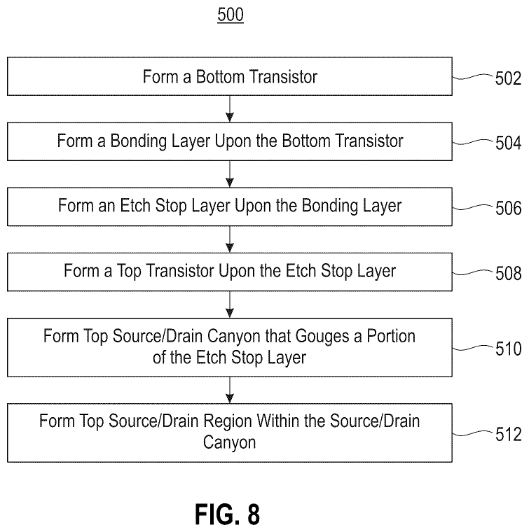

FIG. 8 depicts a flow diagram illustrating a method 500 to fabricate a semiconductor IC device, such as semiconductor IC device 400. The depicted fabrication operations of method 500 may be illustratively depicted and described above with reference to one or more of FIG. 3 through FIG. 7 of the drawings, which describe the fabrication of semiconductor IC device 100, 300, 400, or the like, though various fabrication operations described in method 500 may be used to fabricate other types of semiconductor IC devices. The method 500 depicted herein is illustrative. There can be many variations to the diagram or operations described therein without departing from the spirit of the embodiments. For instance, the operations can be performed in a differing order, or operations can be added, deleted, or modified. Method 500 may begin at block 502 with forming a bottom transistor. For example, semiconductor IC device 100 may be formed. At block 504, method 500 may continue with forming a bonding layer upon the bottom transistor. For example, bonding layer 202 may be formed upon the semiconductor IC device 100. At block 506, method 500 may continue with forming an etch stop layer and directly connecting the etch stop layer to the bonding layer. For example, etch stop layer 204 may be formed in the formation of semiconductor IC device 300 and the etch stop layer 204 of the semiconductor IC device 300 may be directly connected to the bonding layer 202 of the semiconductor IC device 100.

At block 508, method 500 may continue with forming a top transistor upon the etch stop layer. The formation of the top transistor includes, for example at block 510, forming a top source/drain canyon that gouges a portion of the etch stop layer and, for example at block 512, forming a top source/drain region within the source/drain canyon. The gouge within the etch stop layer is directly under a bottom surface of the top S/D region. For example, top source/drain canyon 406 gouges a portion of the etch stop layer 204. Subsequently, top source/drain region 420 is formed within the source/drain canyon 406. The gouge 410 within the etch stop layer 204 is directly under a bottom surface of the top S/D region 420.

The semiconductor IC devices described herein may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a top transistor comprising a top source/drain (S/D) region;
a bottom transistor; and
an etch stop bonding structure comprising a bonding layer directly connected to the bottom transistor and an etch stop layer directly connected to the top transistor.

2. The semiconductor IC device of claim 1, further comprising:
a gouge within the etch stop layer directly under a bottom surface of the top S/D region.

3. The semiconductor IC device of claim 2, wherein the etch stop layer has a dielectric constant (κ) of four or less.

4. The semiconductor IC device of claim 2, wherein a horizontal length of the top S/D region is substantially the same as a horizontal length of the gouge.

5. The semiconductor IC device of claim 2, further comprising:
a first bottommost inner spacer directly connected to the etch stop layer and directly connected to the S/D region; and
a second bottommost inner spacer directly connected to the etch stop layer and directly connected to the S/D region.

6. The semiconductor IC device of claim 5, wherein the first bottommost inner spacer is further directly connected to a first gate structure and wherein the second bottommost inner spacer is further directly connected to a second gate structure.

7. The semiconductor IC device of claim 2, wherein a horizontal length of the top S/D region is greater than a horizontal length of the gouge.

8. The semiconductor IC device of claim 5, wherein a horizontal length of the top S/D region is less than a horizontal length of the gouge.

9. The semiconductor IC device of claim 8, wherein the gouge is between at least a portion of a bottom surface of the first bottommost inner spacer and the etch stop layer and between at least a portion of a bottom surface of the second bottommost inner spacer and the etch stop layer.

10. The semiconductor IC device of claim 2, wherein the gouge is substantially filled with air.

11. The semiconductor IC device of claim 2, wherein the gouge is substantially filled with the top S/D region.

12. The semiconductor IC device of claim 3, wherein the gouge is substantially filled with a dielectric material that is different from the etch stop layer.

13. A semiconductor integrated circuit (IC) device comprising:
a top transistor comprising a top source/drain (S/D) region;
a bottom transistor comprising a bottom S/D region inline and below the top S/D region; and
an etch stop bonding structure comprising a bonding layer directly connected to the bottom transistor and an etch stop layer directly connected to the top transistor.

14. The semiconductor IC device of claim 13, further comprising:
a gouge within the etch stop layer directly under a bottom surface of the top S/D region.

15. The semiconductor IC device of claim 14, wherein a horizontal length of the top S/D region is substantially the same as a horizontal length of the gouge.

16. The semiconductor IC device of claim 14, wherein a horizontal length of the top S/D region is greater than a horizontal length of the gouge.

17. The semiconductor IC device of claim 14, wherein a horizontal length of the top S/D region is less than a horizontal length of the gouge.

18. The semiconductor IC device of claim 14, wherein the gouge is substantially filled with air.

19. The semiconductor IC device of claim 14, wherein the gouge is substantially filled with the top S/D region.

20. A semiconductor integrated circuit (IC) device fabrication method comprising:
forming a bottom transistor;
forming a bonding layer upon the bottom transistor;
forming an etch stop layer and directly connecting the etch stop layer to the bonding layer; and
forming a top transistor upon the etch stop layer, wherein forming the top transistor comprises:
forming a top source/drain canyon that gouges a portion of the etch stop layer; and
forming a top source/drain region within the top source/drain canyon,
wherein the gouge within the etch stop layer is directly under a bottom surface of the top source/drain region.
